(19) United States
(12) Patent Application Publication
(10) Pub. No.: US 2025/0112040 A1
(43) Pub. Date: Apr. 3, 2025

(54) THIN FILM GROWTH MODULATION USING WAFER BOW

(71) Applicant: Lam Research Corporation, Fremont, CA (US)

(72) Inventors: Xin Meng, Ontario, CA (US); Defu Liang, Wilsonville, OR (US); Hu Kang, Tualatin, OR (US); Joseph Lindsey Womack, Tigard, OR (US); Ming Li, West Linn, OR (US)

(21) Appl. No.: 18/832,926

(22) PCT Filed: Jan. 30, 2023
(86) PCT No.: PCT/US2023/011893

§ 371 Date: Jul. 25, 2024

Related U.S. Application Data
(60) Provisional application No. 63/305,179, filed on Jan. 31, 2022.

(51) Int. Cl. H01L 21/02; C23C 16/52

(52) U.S. Cl. CPC H01L 21/02274; C23C 16/52; H01L 21/0228

(57) ABSTRACT

A process chamber and method of modulating thin film growth on a wafer using a plasma-enhanced chemical vapor deposition (PECVD) process is described. During a first deposition phase, a first portion of a film is disposed on a wafer on a pedestal in a process chamber. During a second deposition phase, a second portion of the film is deposited on the wafer. The wafer is unclamped from the pedestal prior to the first and/or second deposition phase and remains unclamped during the first and/or second deposition phase. The wafer has a non-zero wafer bow during unclamped deposition phase to provide a radially non-uniform thickness profile of the film on the wafer.

### PRIORITY CLAIM

This application claims the benefit of priority to U.S. Provisional Patent Application Ser. No. 63/305,179, filed Jan. 31, 2022, which is incorporated herein by reference in its entirety.

### TECHNICAL FIELD

The subject matter disclosed herein generally relates to methods, systems, and machine-readable storage media for film growth modulation using a non-zero wafer bow.

### BACKGROUND

Semiconductor substrate processing systems are used to process semiconductor substrates by techniques including etching, deposition (such as physical vapor deposition (PVD), chemical vapor deposition (CVD), plasma-enhanced chemical vapor deposition (PECVD), atomic layer deposition (ALD), plasma-enhanced atomic layer deposition (PEALD), pulsed deposition layer (PDL), plasma-enhanced pulsed deposition layer (PEPDL), electron-beam evaporation, and sputtering among others), resist removal, and planarization and cleaning. One type of semiconductor substrate processing apparatus is a plasma processing apparatus that includes a vacuum process chamber containing upper and lower electrodes. Radio frequency (RF) power is applied between the electrodes to excite a process gas into plasma for processing (for example, layer deposition) on a substrate (also referred to as a wafer herein) in the chamber.

During plasma processing, the wafer may be clamped to a chuck to present a flat surface to the plasma during, for example, thin film deposition. Generally, electrostatics is used to clamp the wafer; an electrostatic chuck (ESC) is used to reduce the wafer bow (i.e., the distance in height between the center and edges of the wafer) during the thin film deposition. In conventional semiconductor process flows, high wafer bow (e.g., >300-600 μm) may be observed before, during, or even after the thin film deposition. High wafer bow can cause inconsistent thin film deposition due to inconsistent variations from wafer to wafer, from station to station, and from batch to batch. Use of the ESC has not generally proven successful in eliminating the wafer bow and thus variation in thin film deposition. Moreover, as an ESC is a relatively expensive component, some process chambers do not have ESC clamping capability.

The background description provided herein is to generally present the context of the disclosure. It should be noted that the information described in this section is presented to provide the skilled artisan some context for the following disclosed subject matter and should not be considered as admitted prior art. More specifically, work of the presently named inventors, to the extent it is described in this background section, as well as aspects of the description that may not otherwise qualify as prior art at the time of filing, are neither expressly nor impliedly admitted as prior art against the present disclosure.

### SUMMARY

Methods, systems, and computer programs are presented for film growth modulation using a non-zero wafer bow. Some examples modulate film growth during PECVD by inducing or controlling the wafer bow. Some examples modulate film growth and control the wafer bow by dividing wafer deposition into two or more phases.

One example includes forming a film of up to about a few um on a wafer (a thin film), although thicker films may be formed in other examples. In a case where a process chamber includes an ESC or other clamping mechanism, a first deposition phase includes depositing a predetermined percentage of a desired thin film thickness on a wafer that is clamped on the chuck or pedestal (i.e., clamped prior to deposition and remaining clamped during deposition during the first deposition phase). Subsequently, the wafer on the pedestal is unclamped and the remaining portion of the thin film is deposited while the wafer is on the pedestal (but is unclamped) during a second deposition phase. Alternatively, the unclamped deposition phase may precede the clamped deposition phase or may be unclamped during both deposition phases. A multi-phase deposition process that includes clamped and unclamped phases produces a different thin film thickness profile on the wafer compared to a single clamped deposition phase. The allocation of percentage of film thickness in the clamped and unclamped deposition phases may modulate a final thin film thickness profile. A selected allocation of thin film thicknesses deposited in each phase may enable a desired overall film thickness and/or configuration to be created, accordingly.

The non-zero wafer bow can be induced (i.e., created) or changed using one or more methods described herein. For example, in deposition chambers that do not have clamping mechanism, such as an ESC, deposition of a portion of the thin film in a first deposition phase for a wafer that initially has a neutral bow, i.e., a zero bow value, may impart sufficient force on the wafer to induce non-zero wafer bowing. This effect may be considered as “pseudo clamping”. The non-zero wafer bow can be induced or changed by raising the wafer off the pedestal for a predetermined amount of time, discharging a process chamber using inert plasma, re-igniting the plasma, moving the wafer towards or away from the pedestal, or changing the position of the wafer relative to the pedestal. Once the non-zero wafer bow is present, the remaining portion of the thin film may be deposited in a second deposition phase without clamping the wafer. The remaining portion of the thin film in the second deposition phase thus occurs on a non-flat wafer having a desired non-zero wafer bow and produces a different thickness distribution on the wafer compared to the first phase deposition. As a result, the final thickness distribution is different than a thin film deposition that uses a single phase. As above, the allocation of percentage film thicknesses formed during each of the first and second phases can be adjusted to modulate the final thickness profile of the thin film on the wafer. This allows a more consistent deposition on a wafer to be achieved than that of a conventional single step deposition, during which the wafer bow may change and the rate of variation of wafer bow (i.e., wafer bow change rate) can cause an inconsistent thickness profile from wafer to wafer, from station to station, and from batch to batch.

### BRIEF DESCRIPTION OF THE DRAWINGS

Various ones of the appended drawings merely illustrate example embodiments of the present disclosure and should not be considered as limiting its scope.

FIG. 1 illustrates a process chamber, such as a deposition chamber, for manufacturing substrates, according to some example embodiments.

FIG. 2 shows aspects of a process flow for modulating thin film

growth using wafer bow, according to an example.

FIG. 3 is a flow chart including operations in a method of modulating thin film growth, according to an example.

FIG. 4 is a block diagram illustrating an example of a machine upon which one or more example method embodiments may be implemented, or by which one or more example embodiments may be controlled.

### DETAILED DESCRIPTION

Example methods, systems, and computer programs are directed to methods, systems, and machine-readable storage media for thin film growth modulation using wafer bow. Some examples modulate thin film growth during PECVD by controlling wafer bow. For convenience, a thin film is also referred to simply as a “film” in disclosed examples herein. Unless explicitly stated otherwise, components and functions are optional and may be combined or subdivided, and operations may vary in sequence or be combined or subdivided. In the following description, for purposes of explanation, numerous specific details are set forth to provide a thorough understanding of example embodiments. It will be evident to one skilled in the art, however, that the present subject matter may be practiced without these specific details.

As above, the deposition on the wafer causes strain due to the either or both lattice mismatch between the deposited layer and the underlying layers or mismatch in thermal expansion coefficients of the layers deposited on the wafer and the wafer itself; this strain creates an intrinsic non-zero bow of the structure due to the presence of the different materials, which may worsen as the temperature changes (e.g., from a processing temperature to room temperature). Changing the clamping status (i.e., clamped or unclamped) of the wafer during thin film deposition may be used to adjust the growth. For example, unclamping of the wafer mid-growth (i.e., permitting a first portion of the layers to be deposited in a first deposition phase in which the wafer is clamped and a second portion to be deposited in a second deposition phase while the wafer is unclamped) may result in the intrinsic non-zero bow in the wafer being present during the latter stage of deposition (rather than the wafer being forced to be planar by the clamping), thereby changing the deposition characteristics across the wafer due to the changes in proximity to the plasma. The change in deposition characteristics may result in a reduced strain. That is, the deposition in the unclamped phase produces a different thickness distribution on the wafer compared to the deposition in the clamped phase. As a result, the final thin film thickness distribution is more consistent when compared to a wafer deposition formed in a single deposition step.

The wafer bow may be determined using a non-contact technique, such as optical measurement of the wafer surface. Optical measurements may provide the desired sensitivity to the bow, which may be about 1000× smaller than the wafer diameter (bows of up to several hundred um vs wafer diameters of up to about several hundred mm). In some cases, the wafer profile may be measured by scanning a laser over the surface of the wafer at a fixed angle from the surface of the wafer. The deflection of the laser may be measured to determine the curvature of the wafer, and the bow of the wafer may be calculated from the curvature. Alternatively, an optical beam may be focused on the center of the wafer to determine a nominal height, the beam may then be refocused at the edge of the wafer (or a series of locations along the wafer until the edge of the wafer is reached) to determine the height at the edge (or at each location). This optical measurement may be used to calculate the bow, and then the radius of curvature of the wafer may be determined. The bow may be calculated in situ, during the thin film deposition, and/or before and after the thin film deposition.

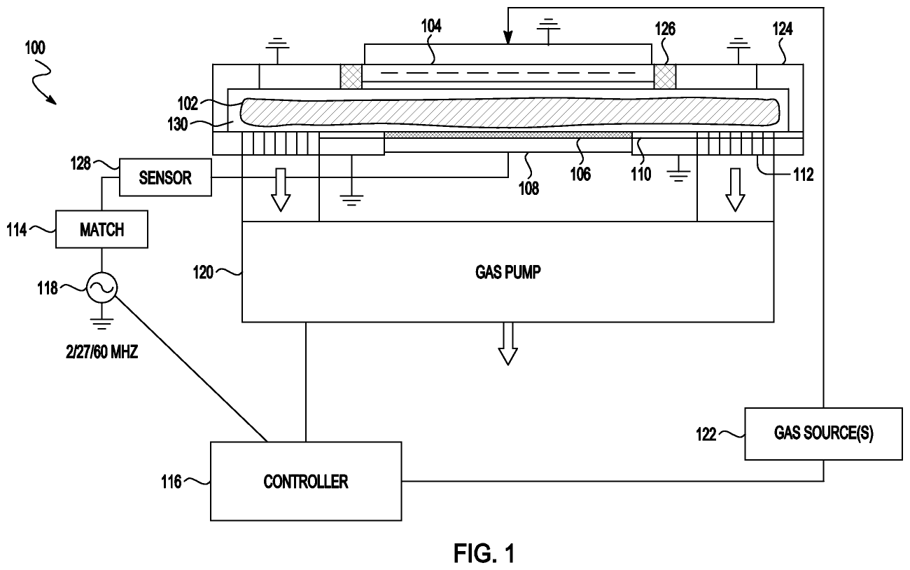

As used herein, the terms “wafer” and “substrate” are used interchangeably. A wafer or substrate indicates a support material upon which, or within which, elements of a semiconductor device are fabricated or attached. A substrate (e.g., substrate 106 in FIG. 1) may include, for example, wafers (e.g., having a diameter of 100 mm, 150 mm, 200 mm, 300 mm, 450 mm, or larger) composed of, for example, elemental semiconductors (e.g., silicon (Si) or germanium (Ge)) or compound semiconductors (e.g., binary compound semiconductors such as silicon germanium (SiGe), gallium arsenide (GaAs) or gallium nitride (GaN), ternary compound semiconductors such as indium gallium arsenide (InGaAs), indium gallium phosphide (InGaP) or indium aluminum arsenide (InAlAs), or quaternary (or beyond) compound semiconductors). Additionally, other substrates include, for example, dielectric materials such as quartz or sapphire (onto which semiconductor materials may be applied). Substrates may be blanket wafers or patterned substrates. A blanket substrate is a substrate that includes a low-surface (or substantially planar) top surface. A patterned substrate is a substrate that includes a high-surface (or structured) top surface. A structured top surface of a substrate may include different high-surface-area structures such as 3D NAND memory holes or other structures.

A general description of a process chamber using the disclosed methods in connection with thin film growth modulation is provided with reference to FIG. 1. FIG. 1 illustrates a process chamber 100 (e.g., a deposition or etching chamber) for manufacturing substrates, according to one embodiment. In some examples, the process chamber 100 may also be referred to as a vacuum chamber. Exciting an electric field between two electrodes is one of the methods to obtain radio frequency (RF) gas discharge in a process chamber. When an oscillating voltage is applied between the electrodes, the discharge obtained is referred to as a capacitively coupled plasma (CCP) discharge.

Plasma 102 may be created within a processing zone 130 of the process chamber 100 utilizing one or more process gases to obtain a wide variety of chemically reactive by-products created by the dissociation of the various molecules caused by electron-neutral collisions. The plasma may be used for deposition of semiconductor thin films using PECVD or etching various materials such as oxides or nitrides. PECVD may be used to deposit semiconductors on substrates at lower temperatures (typically about 250° C. to about 350° C.) than that of standard CVD (typically about 600° C. to about 800° C.), thereby reducing detrimental thermal effects to the substrates such as thermal-enhanced diffusion between existing layers of the wafer. The PECVD may be used to deposit doped or undoped insulating films or semiconductor films such as silicon dioxide (SiO2), silicon nitride (SiN), silicon carbide (SiC), and amorphous silicon (α-Si), among others. For example, silane (SiH4) may be combined with an oxygen source gas form silicon dioxide or a nitrogen gas source to produce silicon nitride.

PECVD may also be used for etching, where the reaction of neutral gas molecules and their dissociated by-products with the molecules of the to-be-etched surface and produce volatile molecules, which may be pumped away. When a plasma is created, the positive ions are accelerated from the plasma across a space-charge sheath separating the plasma from chamber walls to strike the substrate surface with enough energy to remove material from the substrate surface. The process of using highly energetic and chemically reactive ions to selectively and anisotropically remove materials from a substrate surface is called reactive ion etch (RIE). In some examples, the process chamber 100 may be used in connection with PECVD or PEALD deposition processes. In one embodiment, fluorocarbon gases, such as CF₄ and C₄F₈, are used in a dielectric etch process for their anisotropic and selective etching capabilities, but the principles described herein may be applied to other plasma-creating gases. The fluorocarbon gases are readily dissociated into chemically reactive by-products that include smaller molecular and atomic radicals. These chemically reactive by-products etch away the dielectric material.

Whether used for deposition or etching, a controller 116 manages the operation of the process chamber 100 by controlling the different elements in the chamber 100, such as RF generator 118, gas sources 122, and gas pump 120. The process chamber 100 illustrates a processing chamber with an upper (or top) electrode 104 and a lower (or bottom) electrode 108. The upper electrode 104 may be grounded or coupled to an RF generator (not shown), and the lower electrode 108 is coupled to the RF generator 118 via a matching network 114. The RF generator 118 provides an RF signal between the upper electrode 104 and the lower electrode 108 to generate RF power in one or multiple (e.g., two or three) different RF frequencies. According to the desired configuration of the process chamber 100 for a particular operation, at least one of the multiple RF frequencies may be turned ON or OFF. In the embodiment shown in FIG. 1, the RF generator 118 is configured to provide frequencies, such as 400 kHz, 2 MHz, 27 MHz, and 60 MHz; other frequencies are also possible, however.

The process chamber 100 includes a gas showerhead on the top electrode 104 to input process gas into the process chamber 100 provided by the gas source(s) 122, and a perforated confinement ring 112 that allows the gas to be pumped out of the process chamber 100 by gas pump 120. In some example embodiments, the gas pump 120 is a turbomolecular pump, but other types of gas pumps may be utilized.

When substrate 106 is present in the process chamber 100, silicon focus ring 110 is situated next to substrate 106 such that there is a uniform RF field at the bottom surface of the plasma 102 for uniform deposition (or etching) on the surface of the substrate 106. The embodiment of FIG. 1 shows a triode reactor configuration where the upper electrode 104 is surrounded by a symmetric RF ground electrode 124. Insulator 126 is a dielectric that isolates the ground electrode 124 from the upper electrode 104. Other implementations of the process chamber 100, including Inductively Coupled Plasma (ICP)-based implementations, are also possible without changing the scope of the disclosed embodiments.

Each frequency generated by the RF generator 118 may be selected for a specific purpose in the substrate manufacturing process. In the example of FIG. 1, with RF powers provided at 400 kHz, 2 MHz, 27 MHz, and 60 MHz, the 400 kHz or 2 MHz RF power provides ion energy control, and the 27 MHz and 60 MHz powers provide control of the plasma density and the dissociation patterns of the chemistry. This configuration, where each RF power may be turned ON or OFF, enables certain processes that use ultra-low ion energy on the substrates, and certain processes (e.g., soft etch for low-k materials) where the ion energy has to be low (e.g., under 700 or 200 eV).

In another embodiment, a 60 MHz RF power is used on the upper electrode 104 to obtain ultra-low energies and very high density. This configuration allows chamber cleaning with high-density plasma when substrate 106 is not in the process chamber 100 while minimizing sputtering on the ESC surface. The ESC surface is exposed when substrate 106 is not present, and any ion energy on the surface should be avoided, which is why the bottom 2 MHz and 27 MHz power supplies may be off during cleaning.

In an example embodiment, the process chamber 100 further includes a sensor 128 which may be placed between the matching network 114 of the RF generator 118 and the lower electrode 108. The sensor 128 may include a voltage-current (or V-I) sensor configured to generate a plurality of signals (e.g., sensed data) that are indicative of at least one signal characteristic of RF signals generated by the RF generator 118 at a corresponding plurality of time instances. For example, the V-I sensor may generate a plurality of signals that are indicative of one or more of the following signal characteristics of RF signals: voltage, current, phase, delivered power, and impedance. In some examples, the plurality of signals generated by the sensor 128 at the corresponding plurality of time instances may be stored (e.g., in on-chip memory of controller 116 or the sensor 128) and later retrieved (e.g., by the controller 116) for subsequent processing. In other aspects, the plurality of signals generated by the sensor 128 at the corresponding plurality of time instances may be automatically communicated to the controller 116 as they are generated.

Conventionally, film thickness distribution on a wafer can only be modulated by adjusting conventional “process knobs” such as pressure, electrode gap, gas flow, RF power, temperature, and so forth. Some disclosed examples provide a way to modulate thin film growth using non-zero wafer bow, i.e., other than or in addition to using conventional process knobs. Some present examples enable efficient and cost-effective solution for chambers without ESC clamping hardware. Some disclosed examples utilize existing ESC clamping hardware, but rather than holding a wafer clamped throughout an entire deposition, these examples include a two-phase or multi-phase deposition approach to modulate thin film thickness distribution on the wafer by controlling wafer bow. Some disclosed examples do not include any clamping but do include a two-phase or multi-phase deposition to modulate thin film thickness distribution on the wafer to seek to achieve a better consistency of film growth by controlling wafer bow.

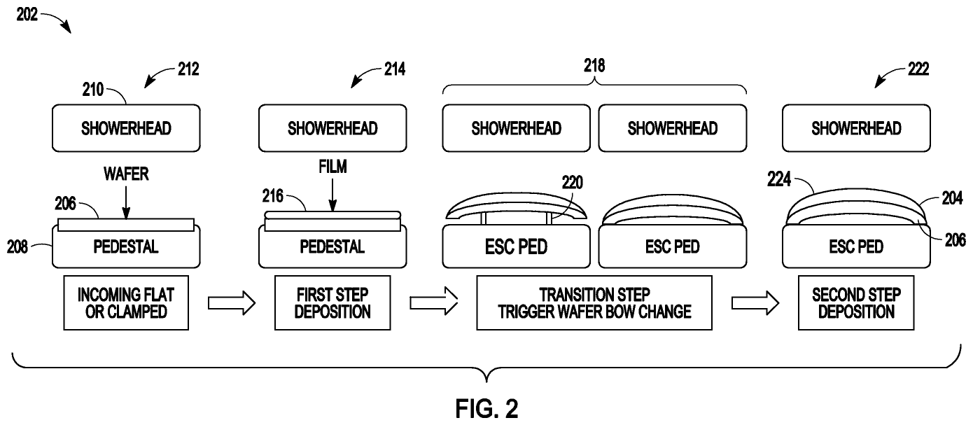

Reference is now made to FIG. 2 of the accompanying drawings. FIG. 2 shows a series of phases from left to right in a process flow (or method) 202 of modulating thin film growth using wafer bow. Some example methods modulate, or control, film thickness growth, i.e., have an ability to control film thickness in a manner or to an extent or dimension that is desired. A deposited film can be created or formed into a desired thickness of material.

As used herein, the terms “chuck” and “pedestal” are used interchangeably. In some examples, a chuck or pedestal includes a clamp; other examples do not include a chuck or pedestal clamp. In some examples, a clamp includes physical clamping mechanism, such as a vacuum applied to the wafer through holes in the top surface of the chuck or platen on which the wafer is disposed. In other examples, a non-physical mechanism may be used, such as an electromagnetic or electrostatic clamping mechanism. In either case, the clamping mechanism can retain a wafer such that the wafer remains essentially flat, i.e., secured against an upper chuck surface or platen during wafer processing. Controlling use of the clamping mechanism during deposition may result in a non-zero wafer bow that is controllably induced into the wafer. For example, a non-zero wafer bow may be controllably induced into a wafer by at least, in a first deposition phase, depositing a first portion of a film onto a wafer clamped on a chuck, subsequently unclamping or releasing the wafer from the chuck at a predetermined time after the first deposition phase, e.g., immediately after the first deposition phase. In a second deposition phase, a second portion of the film is deposited onto the unclamped wafer on the chuck.

In some examples, the non-zero wafer bow may be controllably induced into the wafer in situ, i.e., when the wafer is on the chuck (during one or more of multiple deposition phases); alternatively, or in addition, the non-zero wafer bow may be controllably induced into the wafer before the wafer is clamped onto the chuck, or before the wafer is introduced into a process chamber in which the chuck is situated. The shape of an induced non-zero wafer bow may be controlled to conform to a desired non-zero wafer bow specification, or may be uncontrolled, i.e., no specific wafer bow specification is set for a given process step. In some examples, an induced non-zero wafer bow occurs “automatically” or “naturally” upon release of a clamp; in other examples a non-zero wafer bow is “forced” into a wafer. Here, the wafer may be subjected to a deformation force. That is, the non-zero wafer bow may be induced by growth of the thin film and/or mechanically through physical change of the wafer location on the pedestal (and/or change to parameters such as temperature of the process chamber between phases); at least a portion of the non-zero wafer bow may thus be induced by each means. In some examples, a wafer has an intrinsic non-zero wafer bow shape or value prior to deposition due to existing layers on the wafer.

In some examples, a wafer bow is positive, negative, or zero, i.e., may have a positive, negative, or zero value. A wafer bow value of zero corresponds to a flat wafer. A convex (negative) wafer bow, for example in a dome-shaped wafer, has a negative bow value. In some examples, the inverse situation in which wafer edges are relatively high and the wafer center is relatively low, for example a bowl-shaped wafer having a concave (positive) wafer bow, exhibits a positive bow value. In some examples, a wafer has an inherent bow value that is positive, negative, or zero.

With reference again to FIG. 2, assume in the illustrated example it is desired to form a thin film 204 of a predetermined thickness (e.g., 2000 nm) on a wafer 206 using PECVD in a process chamber. The process chamber may include or be constituted by the process chamber 100 of FIG. 1, for example. In the illustrated view, for clarity of explanation, only the pedestal 208 (or chuck) and a showerhead 210 are shown. During a pre-deposition phase 212, and during subsequent phases in formation of the thin film 204, the wafer 206 is supported on the pedestal 208. In the illustrated example, the pedestal 208 has a clamping mechanism. To that end, the pedestal 208 may include an ESC to apply an electrostatic force to clamp the wafer 206 flat onto the pedestal 208. While the present example is described in relation to a thin film 204 having a modulated thickness of 2000 nm, other film thicknesses are possible; a film thickness of 2000 nm is merely exemplary. Example thin film thicknesses may be in the range about 1000 nm to about 3400 nm, for example. In some examples, thin film thicknesses may be affected by film stress levels.

In a first deposition phase 214, a first deposition on the wafer 206 is performed. In some examples, the first deposition phase 214 is agnostic as to whether the wafer 206 is clamped or unclamped on the pedestal 208. In other examples, the wafer 206 is clamped on the pedestal 208 during the first deposition phase 214.

In the first deposition phase 214, some amount (or percentage of the overall 2000 nm film) of film material is deposited using a plasma to form a first portion 216 of the thin film 204. For purposes of explanation, the first portion 216 of the thin film 204, when formed, has a thickness of “x” nm, where “x” is less than 2000 nm, i.e., less than the overall modulated thickness of the final thin film 204. The thickness of the first portion 216 of the thin film 204 may be substantially uniform over the wafer 206 (e.g., within a few percent across the wafer 206). Example percentage thicknesses of the first portion 216 are discussed below. After formation of the first portion 216, deposition is stopped by turning off the gas sources and/or no longer applying voltages to the electrodes to deactivate the plasma.

At this point, a transition phase 218 is entered while the temperature in the chamber remains the same as that used in the first deposition phase 214. In some examples, a crossover point between the first deposition phase 214 and the transition phase 218 is termination of the deposition in the first deposition phase 214. In some examples, the deposition is terminated whether the wafer 206 is clamped or unclamped.

In the transition phase, after the wafer 206 is no longer clamped, the wafer 206 is allowed to relax from the flat shape forced by the clamping to allow the wafer 206 to adjust to a concave or convex shape due to the intrinsic non-zero bow between the deposited layer and the underlying layers on the wafer 206 and/or induced by application of other force to the wafer 206. In the illustrated example, the wafer 206 has assumed a dome shape, i.e., has a negative bow value.

In some examples, activating lift pins 220 to unseat the wafer 206 off the pedestal 208 enables wafer relaxation and inducement of the non-zero wafer bow. In some examples, the lift pins 220 include sapphire pins that move up to protrude above the pedestal 208 when activated. In some examples, the lift pins 220 run through a pedestal platen and are pushed upwardly by a mechanism located below the pedestal platen (or pedestal 208) to lift the wafer 206 off the pedestal 208 by a predetermined distance. In some examples, a specific wafer lift distance may not be determinative of a desired non-zero wafer bow, but the lift is nevertheless sufficient to allow formation of the intrinsic non-zero wafer bow by a lifted, unclamped wafer. In some examples, the wafer lift distance may induce the non-zero wafer bow by application of an external force (provided by the pins) to the wafer 206. In some examples, the lift distance is approximately a millimeter or other distance that does not drive the wafer 206 into another piece of chamber hardware. In some examples, the amount wafer bow depends on the presence of free clearance of the wafer 206 from the pedestal 208. In some examples, this free clearance allows relaxation to an intrinsic wafer bow induced by the first deposition phase 214 having a maximum wafer bow of, e.g., about 500 μm. A positive or negative wafer bow may be formed.

After a new wafer bow shape is formed during the transition phase 218, a second deposition phase 222 begins. In some examples, regardless of whether the first deposition phase 214 was performed with or without wafer clamping, the second deposition phase 222 is performed without clamping. Thus, in a pedestal including an ESC, no electrostatic clamping force is applied during the second deposition phase 222 (independent of whether the electrostatic clamping force was applied during the first deposition phase 214). The second deposition phase 222 occurs with the wafer 206 in a relaxed shape, albeit bowed with a positive or negative value as a result of the first deposition phase 214 or inherent bow value. In some examples, this wafer shape may be said to assume a natural or resting shape induced by the first deposition phase 214. During the second deposition phase 222, a second portion 224, or the remaining portion of the predetermined thickness of the thin film 204, is formed. In the present example, the second portion 224 of the thin film 204 has a nominal thickness of 2000 nm (the total thickness) minus “x” nm (deposited during the first deposition phase 214).

In some examples, the first deposition phase 214 and second deposition phase 222 are “repeatable”, i.e., can be repeated consistently, or at least with consistent results. This allows repeatable and consistent modulation of the overall thickness and profile of the thin film 204.

As the wafer 206 has a non-zero bow value (usually on the order of tens to a few hundred microns) during the second deposition phase 222, the distance of the wafer 206 from the plasma may vary during deposition, thereby varying the deposition rate due to the comparative differences in plasma density, electric field, and temperature across the wafer 206 (the temperature may vary due to contact with the pedestal 208 and proximity to plasma). This leads to a variation in the thickness profile of the thin film 204 across the wafer 206 at the end of the second deposition phase 222. The thickness variation between the center and edge of the wafer 206 may be up to, for example, about several percent (e.g., 7%) of the total film thickness, which may be small enough to not appreciably affect the characteristics of the thin film 204. The thickness may be determined based on the process time to deposit the nominal thickness of a flat (i.e., clamped) wafer. In some examples, the ratio of film thickness deposited during the first deposition phase 214 to that deposited during the second deposition phase 222 may be determined based on the maximum permitted thickness variation (or variation in profile) across the wafer 206 when the thickness variations caused by the first deposition phase 214 and the second deposition phase 222 are known. In some examples, the bowed shape of the wafer 206 on the pedestal 208 influences the relative deposition rate radially on the wafer 206. In some examples, deposition rates are continuous across the wafer 206 as a function of radius from the center of the wafer 206. In other words, the overall thickness of the thin film 204 is continuous in a radial direction of the wafer 206 and is the same for all points having the same radius from the center of the wafer 206.

In some examples, the center of the wafer 206 lies at an origin or zero radius with the edge of the wafer 206 being at 150 millimeters radius for a standard 300-millimeter wafer. A two-(or more) phase deposition method including an inducement of wafer bow can thus address issues caused by conventional single deposition methods as described above. In some present examples including a two-phase (or multi-phase) deposition, it has been observed that the rate of deposition changes between the wafer center and edge due to the change in shape, or curvature, of the wafer. Some examples change the deposition thickness profile as a function of radius.

Some examples use or leverage at least two distinct portion profiles created by the first deposition phase 214 and the second deposition phase 222 with a deposition rate profile, or a thickness profile, that is different to the first deposition phase 214. These differential deposition processes can create a desired, or beneficial, final thin film thickness or profile. The final film thickness or profile results from a combination of two deposition phases. In some examples, allowing the wafer shape to relax and change the bow increases deposition effects to modulate film thickness and profile. In some examples, the deposition rate at the center of the wafer increases compared to the deposition rate at the edge of the wafer. Some examples produce overall a repeatably uniform thickness profile by depositing the material forming the thin film in two or more phases rather than a single phase. In some examples, the bow shape formed after the first deposition phase is repeatable and serves as a consistent base to modulate a film thickness in the second deposition phase. Within some normal variability wafer to wafer, station to station, hardware set to hardware set, the wafer bow inducement and film modulation is repeatable.

In some examples, the percentage thickness of the first portion 216 of the film based on the overall thickness of the thin film 204 is in a range of 10% to 90%. In some examples, the percentage thickness of the first portion 216 of the film based on the overall thickness of the thin film 204 is in a range of 30% to 70%. In some examples, the percentage thickness of the first portion 216 of the film based on the overall thickness of the thin film 204 is 50%, plus or minus 2%. In some examples, an allocation of a percentage of film thickness in the first and second phases can modulate the final thickness profile. In some cases, the wafer bow can change during a single step deposition, and the rate of variation of wafer bow (i.e., wafer bow change rate) can cause an inconsistent thickness profile from wafer to wafer, from station to station, and from batch to batch. Consistent deposition on wafers can be achieved, or at least targeted, by selectively allocating the percentage of film thickness in the first step and second deposition phases.

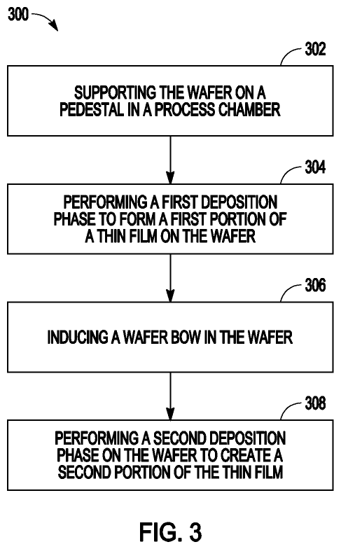

Some examples include methods of forming a film on a wafer. One example is shown in FIG. 3. In some embodiments, not all of the operations may be performed in the method 300 and/or other operations may be present. With reference to FIG. 3, the method 300 of modulating film growth on a wafer includes: at operation 302, positioning the wafer on a pedestal in a process chamber; at operation 304, depositing a first portion of a film on the wafer during first deposition phase; and at operation 306, depositing a second portion of the film on the wafer during a second deposition phase. The wafer is unclamped from the pedestal prior to at least one of the first deposition phase or second deposition phase and remains unclamped during the at least one of the first deposition phase or second deposition phase. During the second deposition phase, the wafer has a non-zero wafer bow.

In some examples, the second portion of the thin film is a remaining portion of the thin film, the first and second portions of the thin film defining an overall thickness of the thin film.

In some examples, the method 300 further comprises clamping the wafer to the pedestal during the first deposition phase.

In some examples, the method 300 further comprises unclamping the wafer from the pedestal after the first deposition phase.

In some examples, the non-zero wafer bow is induced by performance of the first deposition phase. In some examples, the non-zero wafer bow is induced by a formation of the first portion of the thin film on the wafer.

In some examples, the wafer is unclamped during the first deposition phase.

In some examples, the wafer is unclamped during the second deposition phase.

In some examples, the wafer is unclamped during the first deposition phase and the second deposition phase.

In some examples, the wafer is clamped during the first deposition phase and unclamped during the second deposition phase.

In some examples, a percentage thickness of the first portion of the thin film based on an overall thickness of the thin film is in a range of 10% to 90%. In some examples, the percentage thickness of the first portion of the thin film based on the overall thickness of the thin film is in a range of 30% to 70%. In some examples, the percentage thickness of the first portion of the thin film based on the overall thickness of the thin film is in a range of 48% to 52%.

In some examples, the method 300 further comprises adjusting the percentage thickness of the first portion of the thin film, or a percentage thickness of the second portion of the thin film, to modulate an overall thickness or profile of the thin film.

In some examples, the method 300 further comprises forming a first predetermined profile of the first portion of the thin film during the first deposition phase.

In some examples, the method 300 further comprises forming a second predetermined profile of the second portion of the thin film during the second deposition phase.

In some examples, the method 300 further comprises forming a first predetermined profile of the first portion of the thin film during the first deposition phase and forming a second predetermined profile of the second portion of the thin film during the second deposition phase, wherein the first and second profiles are different.

In some examples, a thickness of the first portion of the thin film is constant in a radial direction of the wafer.

In some examples, a thickness of the second portion of the thin film is constant in a radial direction of the wafer.

In some examples, a thickness of the first portion of the thin film is constant in a radial direction of the wafer, and wherein a thickness of the second portion of the thin film is constant in a radial direction of the wafer, and wherein the respective thicknesses of the first and second portions are different from each other.

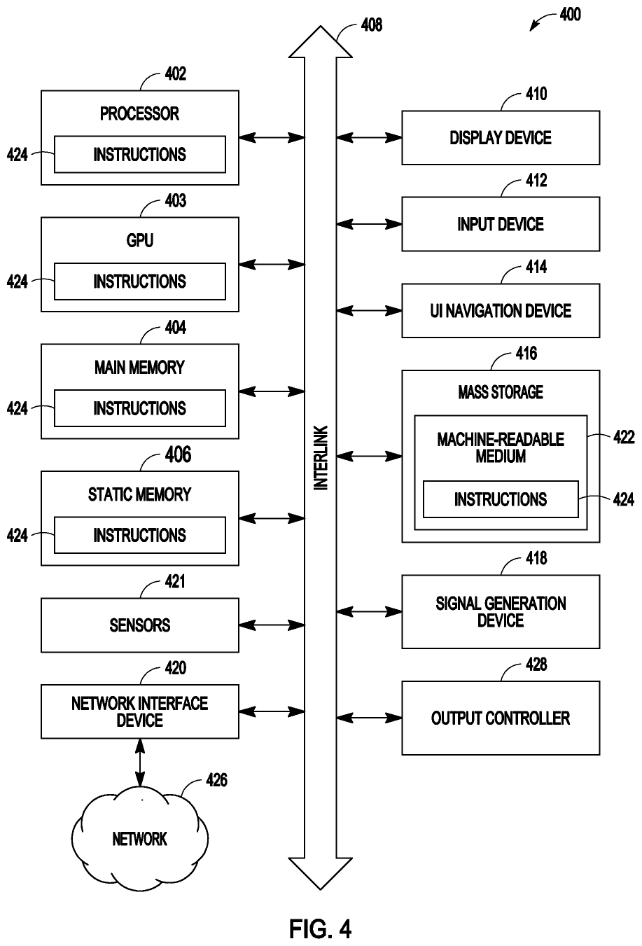

FIG. 4 is a block diagram illustrating an example of a machine 400 upon or by which one or more example process embodiments described herein may be implemented or controlled. In alternative embodiments, the machine 400 may operate as a standalone device or may be connected (e.g., networked) to other machines. In various examples, some of the components shown in FIG. 4 may not be present and/or other components may be present. In a networked deployment, the machine 400 may operate in the capacity of a server machine, a client machine, or both in server-client network environments. In an example, the machine 400 may act as a peer machine in a peer-to-peer (P2P) (or other distributed) network environment. Further, while only a single machine 400 is illustrated, the term “machine” shall also be taken to include any collection of machines that individually or jointly execute a set (or multiple sets) of instructions to perform any one or more of the methodologies discussed herein. Thus, for example, the instructions may be programmed into, or otherwise supplied to various machines that operate the PECVD chamber to provide the methods disclosed herein.

Examples, as described herein, may include, or may operate by, logic, several components, or mechanisms. Circuitry is a collection of circuits implemented in tangible entities that include hardware (e.g., simple circuits, gates, logic). Circuitry membership may be flexible over time and underlying hardware variability. Circuitries include members that may, alone or in combination, perform specified operations when operating. In an example, the hardware of the circuitry may be immutably designed to carry out a specific operation (e.g., hardwired). In an example, the hardware of the circuitry may include variably connected physical components (e.g., execution units, transistors, simple circuits) including a computer-readable medium physically modified (e.g., magnetically, electrically, by the moveable placement of invariant massed particles) to encode instructions of the specific operation. In connecting the physical components, the underlying electrical properties of a hardware constituent are changed (for example, from an insulator to a conductor or vice versa). The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In some examples, any of the physical components may be used in more than one member of more than one circuitry. For example, under operation, execution units may be used in a first circuit of a first circuitry at one point in time and reused by a second circuit in the first circuitry, or by a third circuit in a second circuitry, at a different time.

The machine (e.g., computer system) 400 may include a hardware processor 402 (e.g., a central processing unit (CPU), a hardware processor core, or any combination thereof), a graphics processing unit (GPU) 403, a main memory 404, and a static memory 406, some or all of which may communicate with each other via an interlink (e.g., bus) 408. The machine 400 may further include a display device 410, an alphanumeric input device 412 (e.g., a keyboard), and a user interface (UI) navigation device 414 (e.g., a mouse). In an example, the display device 410, alphanumeric input device 412, and UI navigation device 414 may be a touch screen display. The machine 400 may additionally include a mass storage device (e.g., drive unit) 416, a signal generation device 418 (e.g., a speaker), a network interface device 420, and one or more sensors 421, such as a Global Positioning System (GPS) sensor, compass, accelerometer, or another sensor. The machine 400 may include an output controller 428, such as a serial (e.g., universal serial bus (USB)), parallel, or other wired or wireless (e.g., infrared (IR), near field communication (NFC)) connection to communicate with or control one or more peripheral devices (e.g., a printer, card reader).

In an example embodiment, the hardware processor 402 may perform the functionalities of the controller 116 discussed herein.

The mass storage device 416 may include a machine-readable medium 422 on which is stored one or more sets of data structures or instructions 424 (e.g., software) embodying or utilized by any one or more of the techniques or functions described herein. The instructions 424 may also reside, completely or at least partially, within the main memory 404, within the static memory 406, within the hardware processor 402, or within the GPU 403 during execution thereof by the machine 400. In an example, one or any combination of the hardware processor 402, the GPU 403, the main memory 404, the static memory 406, or the mass storage device 416 may constitute machine-readable media. The instructions 424 may permit the machine 400 to perform any of the operations described herein, such as controlling the components in the deposition chamber.

While the machine-readable medium 422 is illustrated as a single medium, the term “machine-readable medium” may include a single medium or multiple media, (e.g., a centralized or distributed database, and/or associated caches and servers) configured to store the one or more instructions 424.

The term “machine-readable medium” may include any medium that is capable of storing, encoding, or carrying instructions 424 for execution by the machine 400 and that cause the machine 400 to perform any one or more of the techniques of the present disclosure, or that is capable of storing, encoding, or carrying data structures used by or associated with such instructions 424. Non-limiting machine-readable medium examples may include solid-state memories and optical and magnetic media. In an example, a massed machine-readable medium comprises a machine-readable medium 422 with a plurality of particles having invariant (e.g., rest) mass. Accordingly, massed machine-readable media are not transitory propagating signals. Specific examples of massed machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 424 may further be transmitted or received over a communications network 426 using a transmission medium via the network interface device 420.

Implementation of the preceding techniques may be accomplished through any number of specifications, configurations, or example deployments of hardware and software. It should be understood that the functional units or capabilities described in this specification may have been referred to or labeled as components or modules, to emphasize their implementation independence more particularly. Such components may be embodied by any number of software or hardware forms. For example, a component or module may be implemented as a hardware circuit comprising custom very-large-scale integration (VLSI) circuits or gate arrays, off-the-shelf semiconductors such as logic chips, transistors, or other discrete components. A component or module may also be implemented in programmable hardware devices such as field-programmable gate arrays, programmable array logic, programmable logic devices, or the like. Components or modules may also be implemented in software for execution by various types of processors. An identified component or module of executable code may, for instance, comprise one or more physical or logical blocks of computer instructions, which may, for instance, be organized as an object, procedure, or function. Nevertheless, the executables of an identified component or module need not be physically located together but may comprise disparate instructions stored in different locations which, when joined logically together, comprise the component or module and achieve the stated purpose for the component or module.

Indeed, a component or module of executable code may be a single instruction, or many instructions, and may even be distributed over several different code segments, among different programs, and across several memory devices or processing systems. In particular, some aspects of the described process (such as code rewriting and code analysis) may take place on a different processing system (e.g., in a computer in a data center), than that in which the code is deployed (e.g., in a computer embedded in a sensor or robot). Similarly, operational data may be identified and illustrated herein within components or modules and may be embodied in any suitable form and organized within any suitable type of data structure. The operational data may be collected as a single data set or may be distributed over different locations including over different storage devices, and may exist, at least partially, merely as electronic signals on a system or network. The components or modules may be passive or active, including agents operable to perform desired functions.

### EXAMPLES (NOTE THAT “OF EXAMPLES X-Y” IS ANY ONE OR MORE OF EXAMPLES x-y)

Example 1 is a method of modulating film growth on a wafer, the method comprising: depositing, during a first deposition phase, a first portion of a film on a wafer disposed on a pedestal in a process chamber; and depositing, during a second deposition phase, a second portion of the film on the wafer, the wafer being unclamped from the pedestal prior to at least one of the first deposition phase or second deposition phase and remaining unclamped during the at least one of the first deposition phase or second deposition phase.

In Example 2, the subject matter of Example 1 includes, clamping the wafer to the pedestal prior to the first deposition phase, the wafer remaining clamped to the pedestal during the first deposition phase.

In Example 3, the subject matter of Example 2 includes, wherein the wafer has a non-zero wafer bow during the second deposition phase.

In Example 4, the subject matter of Example 3 includes, wherein the non-zero wafer bow is induced by deposition of the first portion of the film on the wafer.

In Example 5, the subject matter of Examples 3-4 includes, mechanically adjusting a position of the wafer on the pedestal to induce at least a portion of the non-zero wafer bow.

In Example 6, the subject matter of Examples 2-5 includes, using an electrostatic chuck (ESC) to clamp the wafer to the pedestal during the first deposition phase.

In Example 7, the subject matter of Examples 1-6 includes, wherein the wafer has a non-zero wafer bow during the at least one of the first deposition phase or second deposition phase.

In Example 8, the subject matter of Examples 1-7 includes, wherein the wafer is unclamped prior to the first deposition phase, the wafer remaining unclamped during the first deposition phase.

In Example 9, the subject matter of Example 8 includes, wherein the wafer remains unclamped during the second deposition phase.

In Example 10, the subject matter of Examples 8-9 includes, wherein the wafer is clamped prior to the second deposition phase and remains clamped during the second deposition phase.

In Example 11, the subject matter of Examples 1-10 includes, determining a ratio of a thickness of the first portion of the film to a thickness of the second portion of the film based on an amount of wafer bow of the wafer to be obtained after the wafer is unclamped.

In Example 12, the subject matter of Examples 1-11 includes, determining a ratio of a thickness of the first portion of the film to a thickness of the second portion of the film based on a predetermined thickness profile of the wafer after the second deposition phase.

In Example 13, the subject matter of Examples 1-12 includes, maintaining a constant temperature within the chamber during the first deposition phase and the second deposition phase.

In Example 14, the subject matter of Examples 1-13 includes, repeating at least one of the first deposition phase or second deposition phase to form the film.

In Example 15, the subject matter of Examples 1-14 includes, forming a first predetermined profile of the first portion of the film during the first deposition phase, and forming a second predetermined profile of the second portion of the film during the second deposition phase, the first predetermined profile and the second predetermined profile being different.

In Example 16, the subject matter of Examples 1-15 includes, wherein a thickness of at least one of the first portion of the film or the second portion is constant in a radial direction of the wafer.

In Example 17, the subject matter of Examples 1-16 includes, wherein the process chamber is a plasma-enhanced chemical vapor deposition (PECVD) chamber.

In Example 18, the subject matter of Examples 1-17 includes, wherein the film is a semiconductor film.

In Example 19, the subject matter of Examples 1-18 includes, wherein the film is an insulating film.

In Example 20, the subject matter of Examples 1-19 includes, wherein: a thickness of the first portion of the film is constant in a radial direction of the wafer, a thickness of the second portion of the film is constant in the radial direction of the wafer, and the thicknesses of the first and second portions are different from each other.

Example 21 is a method of modulating film growth on a wafer, the method comprising: clamping a wafer to a pedestal in a plasma-enhanced chemical vapor deposition (PECVD) chamber; depositing, during a first deposition phase, a first portion of an insulating film on the clamped wafer; unclamping the wafer after the first deposition phase, and depositing, during a second deposition phase, a second portion of the insulating film on the unclamped wafer.

In Example 22, the subject matter of Example 21 includes, wherein the wafer has a non-zero wafer bow during the second deposition phase, and the non-zero wafer bow is induced by deposition of the first portion of the insulating film on the wafer.

In Example 23, the subject matter of Examples 21-22 further comprises determining a ratio of a thickness of the first portion of the insulating film to a thickness of the second portion of the insulating film based on a predetermined thickness profile of the wafer after the second deposition phase.

Example 24 is at least one machine-readable medium including instructions that, when executed by processing circuitry, cause the processing circuitry to perform operations to implement of any of Examples 1-23.

Example 25 is an apparatus comprising means to implement of any of Examples 1-23.

Example 26 is a system to implement of any of Examples 1-23.

Example 27 is a method to implement of any of Examples 1-23.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components for example configurations may be implemented as a combined structure or component. Similarly, structures and functionality presented as a single component may be implemented as separate components. These and other variations, modifications, additions, and improvements fall within the scope of the subject matter herein.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

The claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within the scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

What is claimed is:

1. A method of modulating film growth on a wafer, the method comprising:
depositing, during a first deposition phase, a first portion of a film on a wafer disposed on a pedestal in a process chamber; and
depositing, during a second deposition phase, a second portion of the film on the wafer, the wafer being unclamped from the pedestal prior to at least one of the first deposition phase or second deposition phase and remaining unclamped during the at least one of the first deposition phase or second deposition phase.

2. The method of claim 1, further comprising clamping the wafer to the pedestal prior to the first deposition phase, the wafer remaining clamped to the pedestal during the first deposition phase.

3. The method of claim 2, wherein the wafer has a non-zero wafer bow during the second deposition phase.

4. The method of claim 3, wherein the non-zero wafer bow is induced by deposition of the first portion of the film on the wafer.

5. The method of claim 3, further comprising mechanically adjusting a position of the wafer on the pedestal to induce at least a portion of the non-zero wafer bow.

6. The method of claim 2, further comprising using an electrostatic chuck (ESC) to clamp the wafer to the pedestal during the first deposition phase.

7. The method of claim 1, wherein the wafer has a non-zero wafer bow during the at least one of the first deposition phase or second deposition phase.

8. The method of claim 1, wherein the wafer is unclamped prior to the first deposition phase, the wafer remaining unclamped during the first deposition phase.

9. The method of claim 8, wherein the wafer remains unclamped during the second deposition phase.

10. The method of claim 8, wherein the wafer is clamped prior to the second deposition phase and remains clamped during the second deposition phase.

11. The method of claim 1, further comprising determining a ratio of a thickness of the first portion of the film to a thickness of the second portion of the film based on an amount of wafer bow of the wafer to be obtained after the wafer is unclamped.

12. The method of claim 1, further comprising determining a ratio of a thickness of the first portion of the film to a thickness of the second portion of the film based on a predetermined thickness profile of the wafer after the second deposition phase.

13. The method of claim 1, further comprising maintaining a constant temperature within the chamber during the first deposition phase and the second deposition phase.

14. The method of claim 1, further comprising repeating at least one of the first deposition phase or second deposition phase to form the film.

15. The method of claim 1, further comprising:
forming a first predetermined profile of the first portion of the film during the first deposition phase, and
forming a second predetermined profile of the second portion of the film during the second deposition phase, the first predetermined profile and the second predetermined profile being different.

16. The method of claim 1, wherein a thickness of at least one of the first portion of the film or the second portion is constant in a radial direction of the wafer.

17. The method of claim 1, wherein:
a thickness of the first portion of the film is constant in a radial direction of the wafer,
a thickness of the second portion of the film is constant in the radial direction of the wafer, and
the thicknesses of the first and second portions are different from each other.

18. A method of modulating film growth on a wafer, the method comprising:
clamping a wafer to a pedestal in a plasma-enhanced chemical vapor deposition (PECVD) chamber;
depositing, during a first deposition phase, a first portion of an insulating film on the clamped wafer;
unclamping the wafer after the first deposition phase, and
depositing, during a second deposition phase, a second portion of the insulating film on the unclamped wafer.

19. The method of claim 18, wherein the wafer has a non-zero wafer bow during the second deposition phase, and the non-zero wafer bow is induced by deposition of the first portion of the insulating film on the wafer.

20. The method of claim 18, further comprising determining a ratio of a thickness of the first portion of the insulating film to a thickness of the second portion of the insulating film based on a predetermined thickness profile of the wafer after the second deposition phase.
